(19) United States
(12) Patent Application Publication
(10) Pub. No.: US 2023/0422560 A1
(43) Pub. Date: Dec. 28, 2023

(54) DISPLAY DEVICE AND MANUFACTURING METHOD OF THE SAME

(71) Applicant: Japan Display Inc., Tokyo (JP)

(72) Inventor: Masaru TAKAYAMA, Tokyo (JP)

(73) Assignee: Japan Display Inc., Tokyo (JP)

(21) Appl. No.: 18/341,787

(22) Filed: Jun. 27, 2023

(30) Foreign Application Priority Data
Jun. 27, 2022 (JP) 2022-102782

(51) Int. Cl. H10K 59/122; H10K 59/80; H10K 59/12

(52) U.S. Cl. CPC H10K 59/122; H10K 59/1201; H10K 59/80515

(57) ABSTRACT

According to one embodiment, a display device comprising a first lower electrode, a rib including a first pixel aperture overlapping with the first lower electrode, a partition arranged on the rib, a first upper electrode opposed to the first lower electrode, and a first organic layer located between the first lower electrode and the first upper electrode. The partition includes a lower portion having a first side surface and an upper portion protruding from the first side surface. The first organic layer is in contact with the first side surface.

### CROSS-REFERENCE TO RELATED APPLICATIONS

This application is based upon and claims the benefit of priority from Japanese Patent Application No. 2022-102782, filed Jun. 27, 2022, the entire contents of which are incorporated herein by reference.

### FIELD

Embodiments described herein relate generally to a display device and a manufacturing method of the same.

### BACKGROUND

Recently, display devices with organic light-emitting diodes (OLEDs) applied thereto as display elements have been put into practical use. This display device comprises a lower electrode, an organic layer covering the lower electrode, and an upper electrode covering the organic layer.

A technique of improving reliability is required in manufacturing the above display device.

### BRIEF DESCRIPTION OF THE DRAWINGS

FIG. 1 is a view showing a configuration example of a display device according to one of embodiments.

FIG. 2 is a view showing an example of a layout of sub-pixels.

FIG. 3 is a schematic cross-sectional view showing the display device along line III-III in FIG. 2.

FIG. 4 is a view showing an example of a layer structure applicable to organic layers.

FIG. 5 is a schematic cross-sectional view showing the display device along line V-V in FIG. 2.

FIG. 6 is a schematic cross-sectional view showing the display device along line VI-VI in FIG. 2.

FIG. 7 is a view showing a modified example of the embodiment.

FIG. 8 is a flowchart showing an example of a method of manufacturing the display device.

FIG. 9 is a schematic cross-sectional view showing a part of a display device manufacturing process.

FIG. 10 is a schematic cross-sectional view showing a manufacturing process following FIG. 9.

FIG. 11 is a schematic cross-sectional view showing a manufacturing process following FIG. 10.

FIG. 12 is a schematic cross-sectional view showing a manufacturing process following FIG. 11.

FIG. 13 is a schematic cross-sectional view showing a manufacturing process following FIG. 12.

FIG. 14 is a schematic cross-sectional view showing a manufacturing process following FIG. 13.

FIG. 15 is a schematic cross-sectional view showing a manufacturing process following FIG. 14.

FIG. 16 is a schematic cross-sectional view showing a manufacturing process following FIG. 15.

FIG. 17 is a schematic cross-sectional view showing a manufacturing process following FIG. 16.

### DETAILED DESCRIPTION

In general, according to one embodiment, a display device comprises: a first lower electrode; a rib including a first pixel aperture overlapping with the first lower electrode; a partition arranged on the rib; a first upper electrode opposed to the first lower electrode; and a first organic layer located between the first lower electrode and the first upper electrode, which is in contact with the first lower electrode through the first pixel aperture, and which emits light in accordance with a potential difference between the first lower electrode and the first upper electrode. The partition includes a lower portion having a first side surface and an upper portion protruding from the first side surface. The first organic layer is in contact with the first side surface.

In addition, according to the embodiment, a display device manufacturing method a display device manufacturing method comprises: forming a first lower electrode and a second lower electrode; forming a rib including a first pixel aperture overlapping with the first lower electrode and a second pixel aperture overlapping with the second lower electrode; forming on the rib a partition which includes a lower portion having a first side surface and a second side surface and which includes an upper portion protruding from the first side surface and the second side surface; forming a first organic layer which is in contact with the first lower electrode and the second lower electrode through the first pixel aperture and the second pixel aperture, respectively, and which is in contact with the first side surface and the second side surface; and forming a first upper electrode covering the first organic layer.

According to the embodiment, a display device and a display device manufacturing method capable of improving reliability can be provided.

An embodiment will be described hereinafter with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes and the like, of the respective parts are schematically illustrated in the drawings, compared to the actual modes. However, the schematic illustration is merely an example, and adds no restriction to the interpretation of the invention. In addition, in the specification and drawings, structural elements which function in the same or a similar manner to those described in connection with preceding drawings are denoted by like reference numbers, detailed description thereof being omitted unless necessary.

In the figures, an X-axis, a Y-axis and a Z-axis orthogonal to each other are described to facilitate understanding as needed. A direction along the X-axis is referred to as a first direction, a direction along the Y-axis is referred to as a second direction, and a direction along the Z-axis is referred to as a third direction. Viewing various elements parallel to the third direction Z is referred to as plan view.

The display device of this embodiment is an organic electroluminescent display device comprising an organic light emitting diode (OLED) as a display element, and can be mounted on televisions, personal computers, vehicle-mounted devices, tablet terminals, smartphones, mobile phones, and the like.

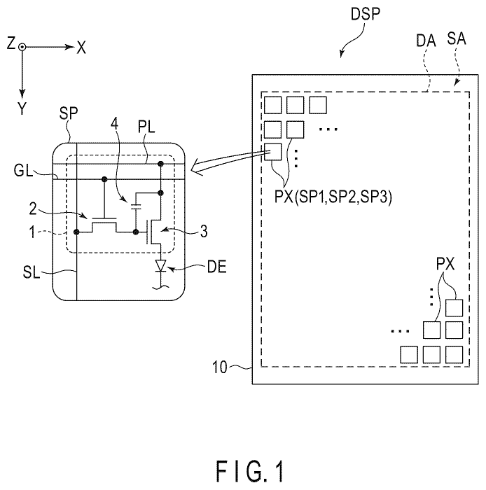

FIG. 1 is a plan view showing a configuration example of a display device DSP according to the embodiment. The display device DSP has a display area DA where images are displayed and a surrounding area SA around the display area DA, on an insulating substrate 10. The substrate 10 may be glass or a flexible resin film.

In the embodiment, the shape of the substrate in plan view is a rectangular shape. However, the shape of the substrate 10 in plan view is not limited to a rectangular shape, but may be any other shape such as a square, a circle or an ellipse.

The display area DA includes a plurality of pixels PX arrayed in a matrix in the first direction X and the second direction Y. Each of the pixels PX includes a plurality of sub-pixels SP. In one example, the pixel PX includes a blue first sub-pixel SP1, a green second sub-pixel SP2, and a red third sub-pixel SP3. The pixel PX may include sub-pixels SP of other colors such as a white color together with the sub-pixels SP1, SP2, and SP3 or instead of any of the sub-pixels SP1, SP2, and SP3.

The sub-pixel SP comprises a pixel circuit 1 and a display element DE driven by the pixel circuit 1. The pixel circuit 1 comprises a pixel switch 2, a drive transistor 3, and a capacitor 4. The pixel switch 2 and the drive transistor 3 are, for example, switching elements constituted by thin-film transistors.

A gate electrode of the pixel switch 2 is connected to a scanning line GL. One of a source electrode and a drain electrode of the pixel switch 2 is connected to a signal line SL, and the other is connected to a gate electrode of the drive transistor 3 and the capacitor 4. In the drive transistor 3, one of the source electrode and the drain electrode is connected to the power line PL and the capacitor 4, and the other is connected to the display element DE. The display element DE is an organic light emitting diode (OLED) serving as a light emitting element.

The configuration of the pixel circuit 1 is not limited to the example shown in the figure. For example, the pixel circuit 1 may comprise more thin-film transistors and capacitors.

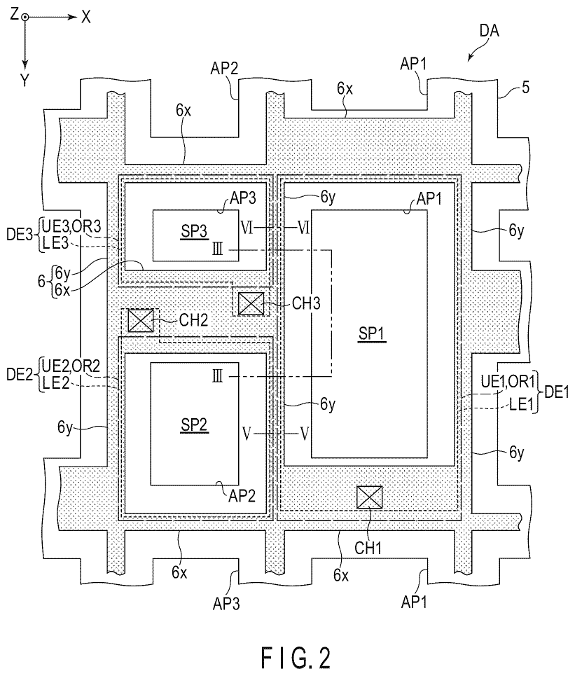

FIG. 2 is a view showing an example of a layout of the sub-pixels SP1, SP2, and SP3. In the example of FIG. 2, the first sub-pixel SP1 and the third sub-pixel SP3 are arranged in the first direction X. The first sub-pixel SP1 and the second sub-pixel SP2 are arranged in the first direction X. Furthermore, the second sub-pixel SP2 and the third sub-pixel SP3 are arranged in the second direction Y.

When the sub-pixels SP1, SP2, and SP3 are arranged in such a layout, a column in which the sub-pixels SP2 and SP3 are alternately arranged in the second direction Y and a column in which a plurality of first sub-pixels SP1 are repeatedly arranged in the second direction Y are formed in the display area DA. These columns are alternately arranged in the first direction X.

The layout of the sub-pixels SP1, SP2, and SP3 is not limited to the example in FIG. 2. As an alternative example, the sub-pixels SP1, SP2, and SP3 in each pixel PX may be arranged in order in the first direction X.

A rib 5 and a partition 6 are arranged in the display area DA. The rib 5 includes a first pixel aperture AP1 in the first sub-pixel SP1, a second pixel aperture AP2 in the second sub-pixel SP2, and a third pixel aperture AP3 in the third sub-pixel SP3.

In the example shown in FIG. 2, the area of the first pixel aperture AP1 is larger than that of the second pixel aperture AP2. The area of the first pixel aperture AP1 is larger than that of the third pixel aperture AP3. Furthermore, the area of the third pixel aperture AP3 is smaller than that of the second pixel aperture AP2.

The partition 6 is arranged at a boundary of adjacent sub-pixels SP and overlaps with the rib 5 in plan view. The partition 6 includes a plurality of first partitions 6x extending in the first direction X and a plurality of second partitions 6y extending in the second direction Y. The plurality of first partitions 6x are arranged between the pixel apertures AP2 and AP3 adjacent to each other in the second direction Y and between two first pixel apertures AP1 adjacent to each other in the second direction Y. The second partitions 6y are arranged between the pixel apertures AP1 and AP2 adjacent to each other in the first direction X and between the pixel apertures AP1 and AP3 adjacent to each other in the first direction X.

In the example in FIG. 2, the first partitions 6x and the second partitions 6y are connected to each other. Thus, the partition 6 has a grating pattern surrounding the pixel apertures AP1, AP2, and AP3 as a whole. The partition 6 is considered to include apertures at the sub-pixels SP1, SP2, and SP3, similarly to the rib 5.

The first sub-pixel SP1 comprises a first lower electrode LE1, a first upper electrode UE1, and a first organic layer OR1 each overlapping with the first pixel aperture AP1. The second sub-pixel SP2 comprises a second lower electrode LE2, a second upper electrode UE2, and a second organic layer OR2 each overlapping with the second pixel aperture AP2. The third sub-pixel SP3 comprises a third lower electrode LE3, a third upper electrode UE3, and a third organic layer OR3 each overlapping with the third pixel aperture AP3.

The first lower electrode LE1, the first upper electrode UE1, and the first organic layer OR1 constitute a first display element DE1 of the first sub-pixel SP1. The second lower electrode LE2, the second upper electrode UE2, and the second organic layer OR2 constitute a second display element DE2 of the second sub-pixel SP2. The third lower electrode LE3, the third upper electrode UE3, and the third organic layer OR3 constitute a third display element DE3 of the third sub-pixel SP3. The display elements DE1, DE2, and DE3 may include a cap layer (optical adjustment layer) to be described below.

The first lower electrode LE1 is connected to the pixel circuit 1 (see FIG. 1) of the first sub-pixel SP1 through a first contact hole CH1. The second lower electrode LE2 is connected to the pixel circuit 1 of the second sub-pixel SP2 through a second contact hole CH2. The third lower electrode LE3 is connected to the pixel circuit 1 of the third sub-pixel SP3 through a third contact hole CH3.

In the example shown in FIG. 2, the contact holes CH2 and CH3 entirely overlap with the first partition 6x between the pixel apertures AP2 and AP3 adjacent to each other in the second direction Y. In addition, the first contact hole CH1 entirely overlaps with the first partition 6x between two first pixel apertures AP1 adjacent to each other in the second direction Y. As an alternative example, at least parts of the contact holes CH1, CH2, and CH3 may not overlap with the first partition 6x.

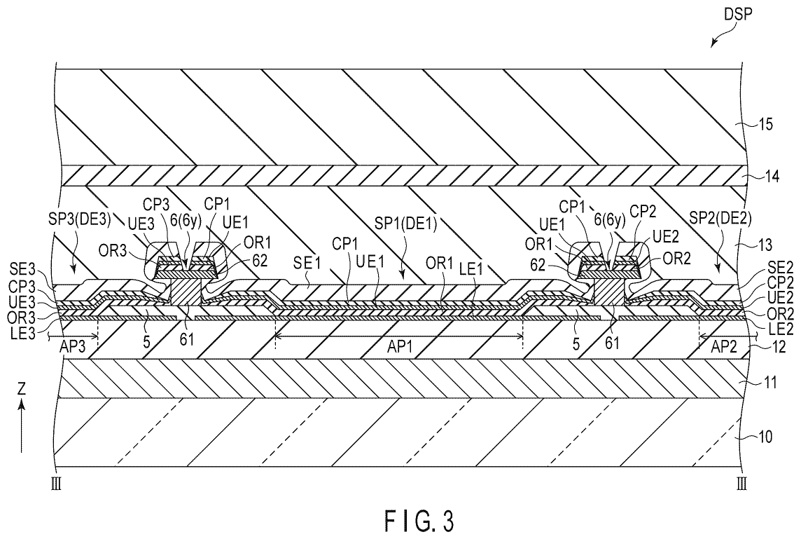

FIG. 3 is a schematic cross-sectional view showing the display device DSP along line III-III in FIG. 2. A circuit layer 11 is arranged on the substrate 10 described above. The circuit layer 11 includes various circuits and lines such as the pixel circuits 1, the scanning lines GL, the signal lines SL and the power lines PL shown in FIG. 1.

The circuit layer 11 is covered with an organic insulating layer 12. The organic insulating layer 12 functions as a planarization film for planarizing uneven parts generated by the circuit layer 11. Although not shown in the cross-section of FIG. 3, the above contact holes CH1, CH2, and CH3 are provided in the organic insulating layer 12.

The lower electrodes LE1, LE2, and LE3 are arranged on the organic insulating layer 12. The rib 5 is arranged on the organic insulating layer 12 and the lower electrodes LE1, LE 2, and LE3. End parts of the lower electrodes LE1, LE2, and LE3 are covered with the rib 5.

The partition 6 includes a lower portion 61 which is conductive and arranged on the rib 5 and an upper portion 62 arranged on the lower portion 61. The upper portion 62 has a width greater than the lower portion 61. As a result, both the end parts of the upper portion 62 protrude beyond the side surfaces of the lower portion 61 in FIG. 3. The shape of the partition 6 may also be referred to as an overhanging shape.

The first organic layer OR1 covers the first lower electrode LE1 through the first pixel aperture AP1. The first upper electrode UE1 covers the first organic layer OR1 and is opposed to the first lower electrode LE1. The second organic layer OR2 covers the second lower electrode LE2 through the second pixel aperture AP2. The second upper electrode UE2 covers the second organic layer OR2 and is opposed to the second lower electrode LE2. The third organic layer OR3 covers the third lower electrode LE3 through the third pixel aperture AP3. The third upper electrode UE3 covers the third organic layer OR3 and is opposed to the third lower electrode LE3.

In the example shown in FIG. 3, a first cap layer CP1 is arranged on the first upper electrode UE1, a second cap layer CP2 is arranged on the second upper electrode UE2, and a third cap layer CP3 is arranged on the third upper electrode UE3. The cap layers CP1, CP2, and CP3 adjust optical properties of the light emitted from the organic layers OR1, OR2, and OR3, respectively.

A first sealing layer SE1 is arranged in the first sub-pixel SP1, a second sealing layer SE2 is arranged in the second sub-pixel SP2, and a third sealing layer SE3 is arranged in the third sub-pixel SP3. The first sealing layer SE1 continuously covers the first cap layer CP1, and the partition 6 around the first sub-pixel SP1. The second sealing layer SE2 continuously covers the second cap layer CP2, and the partition 6 around the second sub-pixel SP2. The third sealing layer SE3 continuously covers the third cap layer CP3, and the partition 6 around the third sub-pixel SP3.

End parts (peripheral parts) of the sealing layers SE1, SE2, and SE3 are located on the upper portions 62. In the example shown in FIG. 3, the end parts of the sealing layers SE1 and SE2 located on the upper portion 62 of the partition 6 between the sub-pixels SP1 and SP2 are separated from each other, and the end parts of the sealing layers SE1 and SE3 located on the upper portion 62 of the partition 6 between the sub-pixels SP1 and SP3 are separated from each other.

The sealing layers SE1, SE2, and SE3 are covered with a resin layer 13. The resin layer 13 is covered with a sealing layer 14. Furthermore, the sealing layer 14 is covered with a resin layer 15.

The organic insulating layer 12 and the resin layers 13 and 15 are formed of an organic material. The rib 5 and the sealing layers 14, SE1, SE2, and SE3 are formed of, for example, an inorganic material such as silicon nitride (SiNx). The rib 5 and the sealing layers 14, SE1, SE2, and SE3 may be formed as a single-layer body of any one of silicon oxide (SiOx), silicon oxynitride (SiON) and aluminum oxide (Al₂O₃). Alternatively, the rib 5 and the sealing layers 14, SE1, SE2, and SE3 may be formed as a stacked-layer body formed of combination of at least two of a silicon nitride layer, a silicon oxide layer, a silicon oxynitride layer, and an aluminum oxide layer.

The lower electrodes LE1, LE2, and LE3 include, for example, a middle layer formed of silver (Ag) and a pair of conductive oxide layers that cover upper and lower surfaces of the middle layer, respectively. Each of the conductive oxide layers can be formed of, for example, a transparent conductive oxide such as indium tin oxide (ITO), indium zinc oxide (IZO), or indium gallium zinc oxide (IGZO).

The upper electrodes UE1, UE2, and UE3 are formed of, for example, a metallic material such as an alloy (MgAg) of magnesium and silver. For example, the lower electrodes LE1, LE2, and LE3 correspond to anodes, and the upper electrodes UE1, UE2, and UE3 correspond to cathodes.

The cap layers CP1, CP2, and CP3 are formed of, for example, multilayer bodies of a plurality of transparent thin films. The multilayer body may include a thin film formed of an inorganic material and a thin film formed of an organic material, as the plurality of thin films. In addition, the plurality of thin films have refractive indexes different from one another. The materials of the thin films constituting the multilayer body are different from the materials of the upper electrodes UE1, UE2, and UE3 and also different from the materials of the sealing layers SE1, SE2, and SE3. The cap layers CP1, CP2, and CP3 may be omitted.

The lower portion 61 of the partition 6 is formed of, for example, aluminum (Al). The lower portion 61 may be formed of an aluminum alloy such as aluminum-neodymium (AlNd) or may have a multilayer structure of an aluminum layer and an aluminum alloy layer. Furthermore, the lower portion 61 may include a thin film formed of a metallic material different from aluminum and an aluminum alloy, under the aluminum layer or the aluminum alloy layer. Such a thin layer can be formed of, for example, molybdenum (Mo).

The upper portion 62 of the partition 6 has, for example, a multilayer structure of a first thin film formed of a metallic material such as titanium (Ti) and a second thin film formed of a conductive material such as ITO. The upper portion 62 may have a single-layer structure of a metallic material such as titanium.

A common voltage is supplied to the partition 6. This common voltage is supplied to each of the upper electrodes UE1, UE2, and UE3 which are in contact with the side surfaces of the lower portion 61. A pixel voltage is supplied to the lower electrodes LE1, LE2, and LE3 through the pixel circuits 1 included in the respective sub-pixels SP1, SP2, and SP3.

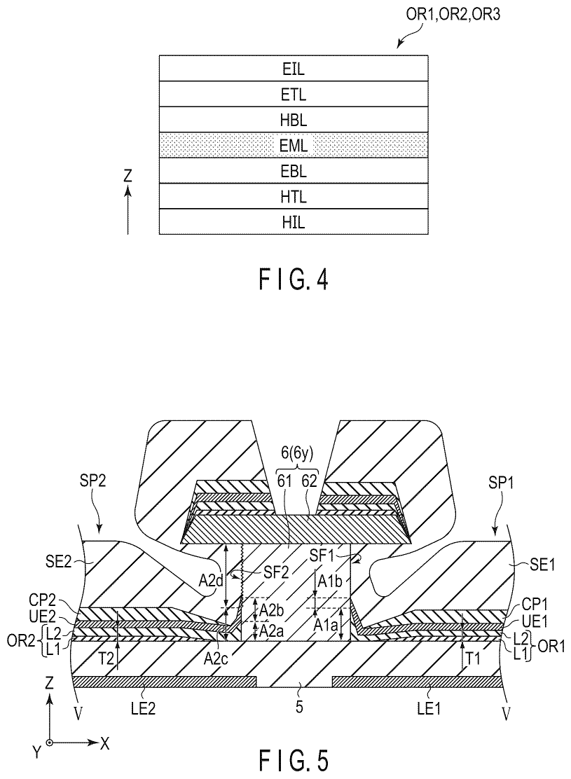

FIG. 4 is a view showing an example of a layer structure applicable to the organic layers OR1, OR2, and OR3. Each of the organic layers OR1, OR2, and OR3 has a structure in which, for example, a hole-injection layer HIL, a hole-transport layer HTL, an electron blocking layer EBL, a light emitting layer EML, a hole blocking layer HBL, an electron-transport layer ETL, and an electron-injection layer EIL are stacked in this order in the third direction Z.

When a potential difference is formed between the first lower electrode LE1 and the first upper electrode UE1, the light emitting layer EML of the first organic layer OR1 emits light of the blue wavelength range. When a potential difference is formed between the second lower electrode LE2 and the second upper electrode UE2, the light emitting layer EML of the second organic layer OR2 emits light of the green wavelength range. When a potential difference is formed between the third lower electrode LE3 and the third upper electrode UE3, the light emitting layer EML of the third organic layer OR3 emits light of the red wavelength range.

FIG. 5 is a schematic cross-sectional view showing the display device DSP along line V-V in FIG. 2, illustrating the partition 6 (second partition 6y) between the first sub-pixel SP1 and the second sub-pixel SP2 and its vicinity. The lower portion 61 has a first side surface SF1 and a second side surface SF2. The first side surface SF1 corresponds to a portion surrounding the first sub-pixel SP1, of the side surface of the partition 6 in the planar shape shown in FIG. 2. The second side surface SF2 corresponds to a portion surrounding the second sub-pixel SP2, of the side surface of the partition 6 in the planar shape shown in FIG. 2. The upper portion 62 protrudes from the side surfaces SF1 and SF2 in the width direction (i.e., the direction parallel to the first direction X) of the partition 6.

The organic layers OR1 and OR2 include a first layer L1 and a second layer L2 which covers the first layer L1. At least the hole-injection layer HIL of the layers shown in FIG. 4 is included in the first layer L1, and the layers which are not included in the first layer L1 are included in the second layer L2. As an example, the first layer L1 is constituted by the hole-injection layer HIL, and the second layer L2 is constituted by the hole-transport layer HTL, the electron blocking layer EBL, the light emitting layer EML, the hole blocking layer HBL, the electron-transport layer ETL, and the electron-injection layer EIL.

The first organic layer OR1 has a thickness T1. The second organic layer OR2 has a thickness T2. In the example of FIG. 5, the thickness T1 is smaller than the thickness T2 (T1<T2). The thickness T1 and the thickness T2 are not limited to this example, but may be equal to each other.

In the present embodiment, the first organic layer OR1 is in contact with the first side surface SF1, and the second organic layer OR2 is in contact with the second side surface SF2. More specifically, the second layer L2 of the first organic layer OR1 is in contact with an area A1a of the first side surface SF1, and the second layer L2 of the second organic layer OR2 is in contact with an area A2a of the second side surface SF2. In contrast, the first layer L1 of the first organic layer OR1 is not in contact with the first side surface SF1. Similarly, the first layer L1 of the second organic layer OR2 is not in contact with the second side surface SF2.

The first upper electrode UE1 is in contact with an area Alb of the first side surface SF1. The second upper electrode UE2 is in contact with an area A2b of the second side surface SF2. The area Alb and the area A2b are located above the area A1a and the area A2a, respectively.

The first side surface SF1 has uniform roughness as a whole. In contrast, the second side surface SF2 includes an area A2c having substantially the same roughness as the first side surface SF1, and an area A2d rougher than the area A2c. The area A2d is located above the area A2c. The area A2a entirely overlaps with the area A2c. The area A2b overlaps with both the area A2c and the area A2d.

In the example of FIG. 5, the height of the area A1a in the third direction Z is different from the height of the area A2a in the third direction Z. More specifically, the height of the area A1a is larger than the height of the area A2a (Ala>A2a).

In addition, in the example of FIG. 5, the width of the area Alb in the third direction Z (i.e., the height direction of the partition 6) is different from the width of the area A2b in the third direction Z. More specifically, the width of the area Alb is smaller than the width of the area A2b (A1b<A2b). The height of the area A2c is equal to the height of the area A1a (A2c=A1a).

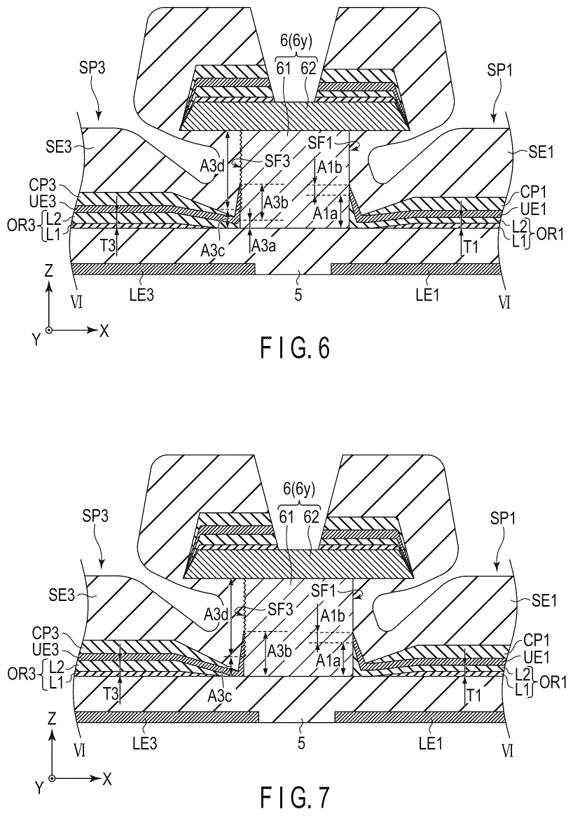

FIG. 6 is a schematic cross-sectional view showing the display device DSP along line VI-VI in FIG. 2, illustrating the partition 6 (second partition 6y) between the first sub-pixel SP1 and the third sub-pixel SP3 and its vicinity. The lower portion 61 has a first side surface SF1 and a third side surface SF3. The first side surface SF1 corresponds to a portion surrounding the first sub-pixel SP1, of the side surface of the partition 6 in the planar shape shown in FIG. 2, as described above. The third side surface SF3 corresponds to a portion surrounding the third sub-pixel SP3, of the side surface of the partition 6 in the planar shape shown in FIG. 2. The upper portion 62 protrudes from the side surfaces SF1 and SF3 in the width direction (i.e., the direction parallel to the first direction X) of the partition 6.

The third organic layer OR3 includes the first layer L1 and the second layer L2, similarly to the first organic layer OR1. The third organic layer OR3 has a thickness T3. In the example of FIG. 6, the thickness T3 is larger than the thickness T1 of the first organic layer OR1 (T1<T3). The thickness T3 is larger than the thickness T2 of the second organic layer OR2 shown in FIG. 5 (T2<T3). The thickness T3 is not limited to this example, but may be equal to the thickness T1 or equal to the thickness T2.

In the example of FIG. 6, the third organic layer OR3 is in contact with the third side surface SF3. More specifically, the second layer L2 of the third organic layer OR3 is in contact with an area A3a of the third side surface SF3, and the first layer L1 of the third organic layer OR3 is not in contact with the third side surface SF3.

The third upper electrode UE3 is in contact with an area A3b of the third side surface SF3. The area A3b is located above the area A3a.

In the cross-section of FIG. 6, the first side surface SF1 has uniform roughness as a whole as well. In contrast, the third side surface SF3 includes an area A3c having substantially the same roughness as the first side surface SF1, and an area A3d rougher than the area A3c. The area A3d is located above the area A3c. The area A3a entirely overlaps with the area A3c. The area A3b overlaps with both the area A3c and the area A3d.

In the example of FIG. 6, the height of the area A1a in the third direction Z is different from the height of the area A3a in the third direction Z. More specifically, the height of the area A1a is larger than the height of the area A3a (A1a>A3a). The height of the area A3a is smaller than the height of the area A2a shown in FIG. 5 (A3a<A2a).

In addition, in the example of FIG. 6, the width of the area Alb in the third direction Z (i.e., the height direction of the partition 6) is different from the width of the area A3b in the third direction Z. More specifically, the width of the area Alb is smaller than the width of the area A3b (A1b<A3b). The width of the area A3b is larger than the width of the area A2b shown in FIG. 5 (A3b>A2b). The height of the area A3c is equal to the height of the area A2a shown in FIG. 5 (A3c=A2a).

FIG. 7 shows a schematic cross-section of the display device DSP along line VI-VI in FIG. 2, similarly to FIG. 6, as a modified example of the present embodiment. In the modified example, the third organic layer OR3 is not in contact with the third side surface SF3. Therefore, the area A3a shown in FIG. 5 does not exist and the area A3b extends. The third organic layer OR3 is entirely covered with the third upper electrode UE3.

In FIG. 5 to FIG. 7, the cross-section of the partition 6 in the direction X (i.e., the cross-section of the second partition 6y) has been focused, and the relationship among the areas A1a, A1b, A2a, A2b, A2c, A2d, A3a, A3b, A3c, and A3d has been described. In the cross-section of the partition 6 in the second direction Y (i.e., the cross-section of the first partition 6x), too, the same relationship among these areas can be established.

Next, a method of manufacturing the display device DSP will be described.

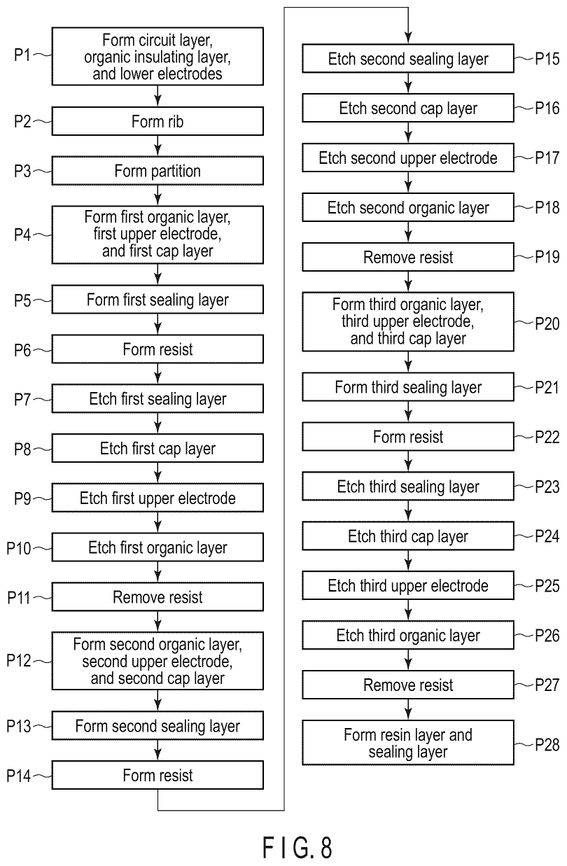

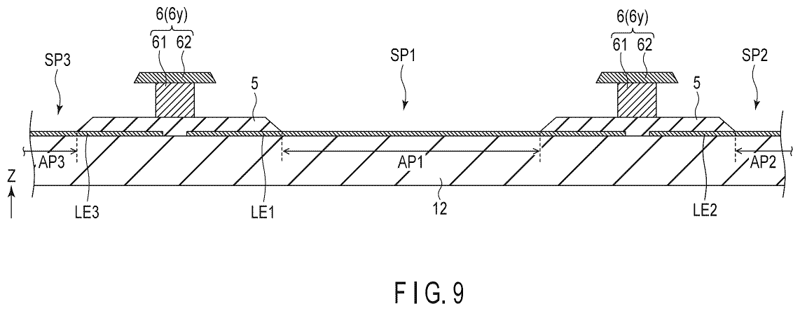

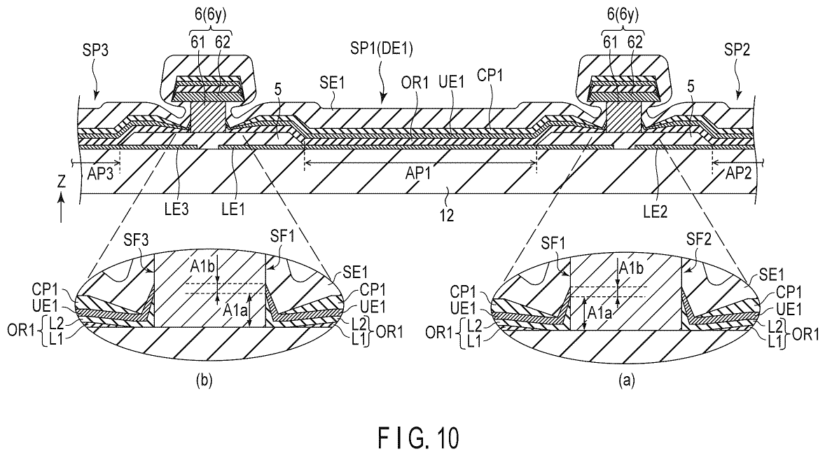

FIG. 8 is a flowchart showing an example of a method of manufacturing the display device DSP. FIG. 9 to FIG. 17 are schematic cross-sectional views showing several parts of a manufacturing process of the display device DSP, respectively. In FIG. 9 to FIG. 17, the substrate 10 and the circuit layer 11 are omitted. FIG. 9 to FIG. 17 correspond to the cross-section along line III-III of FIG. 2, similarly to FIG. 3.

In manufacturing the display device DSP, the circuit layer 11, the organic insulating layer 12, and the lower electrodes LE1, LE2, and LE3 are first formed on the substrate 10 (process P1). Furthermore, the rib is formed shown in FIG. 9 (process P2), and the partition 6 is formed on the rib 5 (process P3). The pixel apertures AP1, AP2, and AP3 of the rib 5 may be formed before process P3 or formed after process P3.

After process P3, as shown in FIG. 10, the first organic layer OR1 which is in contact with the first lower electrode LE1 through the first pixel aperture AP1, the first upper electrode UE1 which covers the first organic layer OR1, and the first cap layer CP1 which covers the first upper electrode UE1 are formed in order by vapor deposition (process P4). Furthermore, the first sealing layer SE1 is formed by Chemical Vapor Deposition (CVD) (process P5). The first sealing layer SE1 continuously covers the first display element DE1 including the first organic layer OR1, the first upper electrode UE1, and the first cap layer CP1, and the partition 6.

The first organic layer OR1, the first upper electrode UE1, the first cap layer CP1, and the first sealing layer SE1 are formed in at least the entire display area DA, and are arranged not only in the first sub-pixel SP1 but also in the second sub-pixel SP2 and the third sub-pixel SP3. The first organic layer OR1, the first upper electrode UE1, and the first cap layer CP1 are divided by the overhanging partition 6.

As expanded and shown in FIGS. 10(a) and (b), the first organic layer OR1 and the first upper electrode UE1 are in contact with the first side surface SF1 of the lower portion 61 of the partition 6. The areas A1 and A1b shown in FIG. 5 are thereby formed. The first organic layer OR1 and the first upper electrode UE1 are also in contact with the second side surface SF2 and the third side surface SF3 of the lower portion 61.

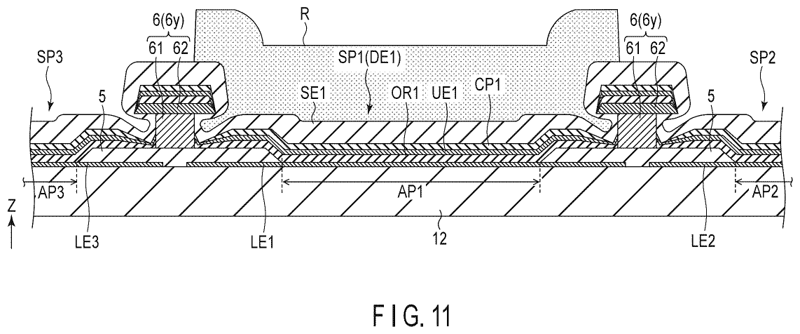

After process P5, a resist R is arranged on the first sealing layer SE1 as shown in FIG. 11 (process P6). The resist R covers the first sub-pixel SP1 and a part of the partition 6 in the surrounding of the first sub-pixel SP1.

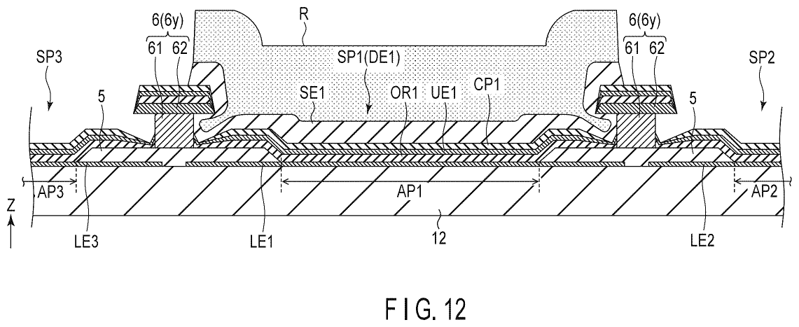

After that, a part of the first sealing layer SE1, which is exposed from the resist R, is removed as shown in FIG. 12, by dry etching using the resist R as a mask (process P7). For example, an etching gas containing fluorine is used for the dry etching. The first cap layer CP1 and the first upper electrode UE1 function as etching stoppers for the dry etching.

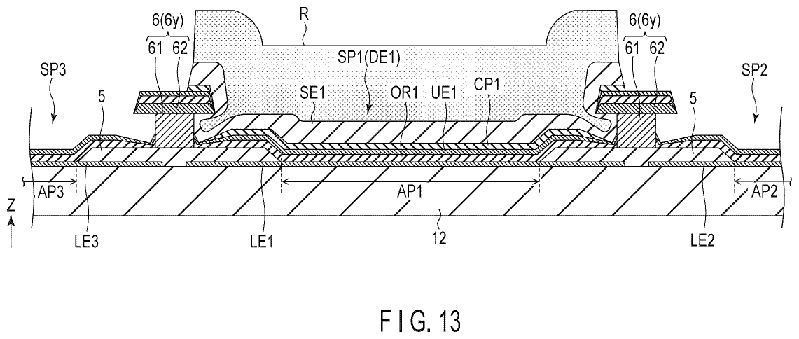

After process P7, a part of the first cap layer CP1, which is exposed from the resist R, is removed as shown in FIG. 13, by etching using the resist R as a mask (process P8). For example, when the first cap layer CP1 has a multilayer structure, the etching includes wet etching or asking for each layer.

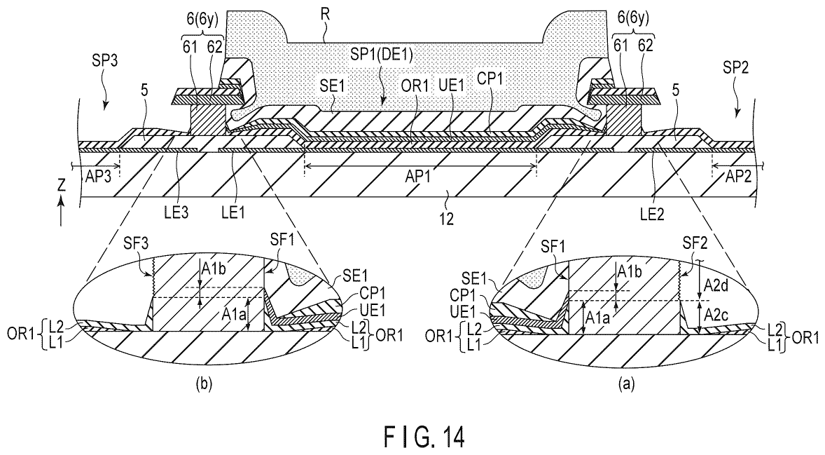

After process P8, the portion of the first upper electrode UE1, which is exposed from the resist R, is removed as shown in FIG. 14, by wet etching using the resist R as a mask (process P9). The first organic layer OR1 functions as an etching stopper for the wet etching.

As expanded and shown in FIG. 14(a), the first upper electrode UE1 which is in contact with the second side surface SF2 is removed to expose the first organic layer OR1, in the second sub-pixel SP2. An area of the second side surface SF2, which is not covered with the first organic layer OR1, is subjected to wet etching in process P9. At this time, fine protrusions and recesses are formed on the second side surface SF2, and the area A2d shown in FIG. 5 is formed. As expanded and shown in FIG. 14(b), fine protrusions and recesses can also be formed on the third side surface SF3. In contrast, the area A2c covered with the first organic layer OR1 at the wet etching in process P9 is protected from the wet etching.

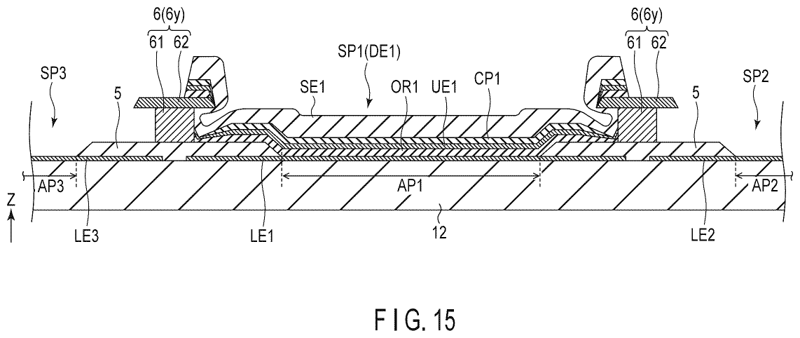

After process P9, a part of the first organic layer OR1, which is exposed from the resist R, is removed as shown in FIG. 15, by etching (asking) using the resist R as a mask (process P10). After that, the resist R is removed (process P11). As a result, as shown in FIG. 15, a substrate in which the first display element DE1 and the first sealing layer SE1 are formed in the first sub-pixel SP1 and no display elements or sealing layers are formed in the second sub-pixel SP2 and the third sub-pixel SP3 can be obtained.

The second display element DE2 is formed in the same procedure as the first display element DE1. More specifically, the second organic layer OR2 which is in contact with the second lower electrode LE2 through the second pixel aperture AP2, the second upper electrode UE2 which covers the second organic layer OR2, and the second cap layer CP2 which covers the second upper electrode UE2 are formed in order by vapor deposition (process P12), and the second sealing layer SE2 continuously covering the second cap layer CP2 and the partition 6 is formed by CVD (process P13).

After that, the resist R covering the second sub-pixel SP2 and a part of the partition 6 in the surrounding of the second sub-pixel SP2 is arranged, similarly to process P6 (process P14). Furthermore, a part of the second sealing layer SE2, which is exposed from the resist R, is removed similarly to process P7 (process P15), a part of the second cap layer CP2, which is exposed from the resist R, is removed similarly to process P8 (process P16), a part of the second upper electrode UE2, which is exposed from the resist R, is removed similarly to process P9 (process P17), and a part of the second organic layer OR2, which is exposed from the resist R, is removed similarly to process P10 (process P18). After that, the resist R is removed (process P19).

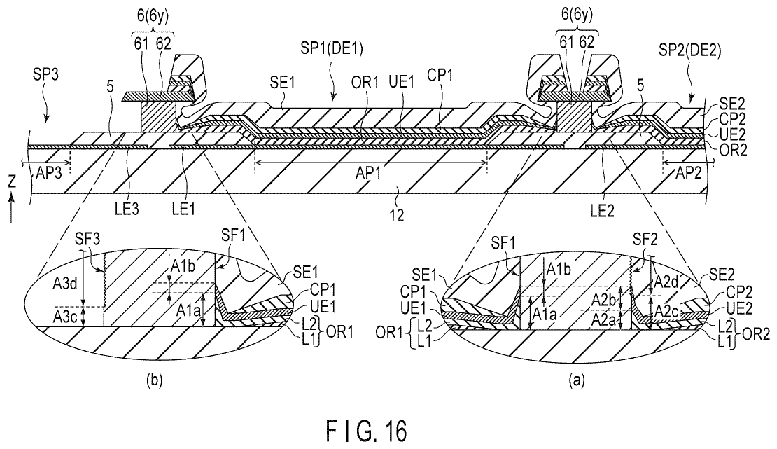

After processes P12 to P19 described above, as shown in FIG. 16, a substrate in which the first display element DE1 and the first sealing layer SE1 are formed in the first sub-pixel SP1, the second display element DE2 and the second sealing layer SE2 are formed in the second sub-pixel SP2, and no display elements or sealing layers are formed in the third sub-pixel SP3 can be obtained.

As expanded and shown in FIG. 16(a), the second organic layer OR2 is in contact with the second side surface SF2. The second organic layer OR2 is formed such that the height of the area A2a which is in contact with the second side surface SF2 is smaller than the height of the area Ala. For example, the height of the area A2a can be adjusted depending on the deposition conditions during forming the second organic layer OR2, for example, an angle of extension of the deposition material released from a deposition source.

As described above, the height of the area A1a is equal to the height of the area A2c. Therefore, when the height of the area A2a is smaller than the height of the area A1a, the second upper electrode UE2 is also in contact with the area A2c.

The deposition conditions during forming the second upper electrode UE2 are the same as the deposition conditions during forming the first upper electrode UE1. Therefore, the second upper electrode UE2 is deposited on the second side surface SF2 at the same height as the first upper electrode UE1 deposited on the first side surface SF1. As a result, the width of the area A2b where the second upper electrode UE2 is in contact with the second side surface SF2 is larger than the width of the area Alb where the first upper electrode UE1 is in contact with the first side surface SF1.

In process P17, a part of the third side surface SF3 of the lower portion 61 adjacent to the third sub-pixel SP3, which is not covered with the second organic layer OR2, is subjected to wet etching for the second upper electrode UE2. As expanded and shown in FIG. 16(b), fine protrusions and recesses are formed in the area subjected to the wet etching, and the area A3d shown in FIG. 6 is formed.

The third display element DE3 is also formed in the same procedure as the first display element DE1. More specifically, the third organic layer OR3 which is in contact with the third lower electrode LE3 through the third pixel aperture AP3, the third upper electrode UE3 which covers the third organic layer OR3, and the third cap layer CP3 which covers the third upper electrode UE3 are formed in order by vapor deposition (process P20), and the third sealing layer SE3 continuously covering the third cap layer CP3 and the partition 6 is formed by CVD (process P21).

After that, the resist R covering the third sub-pixel SP3 and a part of the partition 6 in the surrounding of the third sub-pixel SP3 is arranged, similarly to process P6 (process P22). Furthermore, a part of the third sealing layer SE3, which is exposed from the resist R, is removed similarly to process P7 (process P23), a part of the third cap layer CP3, which is exposed from the resist R, is removed similarly to process P8 (process P24), a part of the third upper electrode UE3, which is exposed from the resist R, is removed similarly to process P9 (process P25), and a part of the third organic layer OR3, which is exposed from the resist R, is removed similarly to process P10 (process P26). After that, the resist R is removed (process P27).

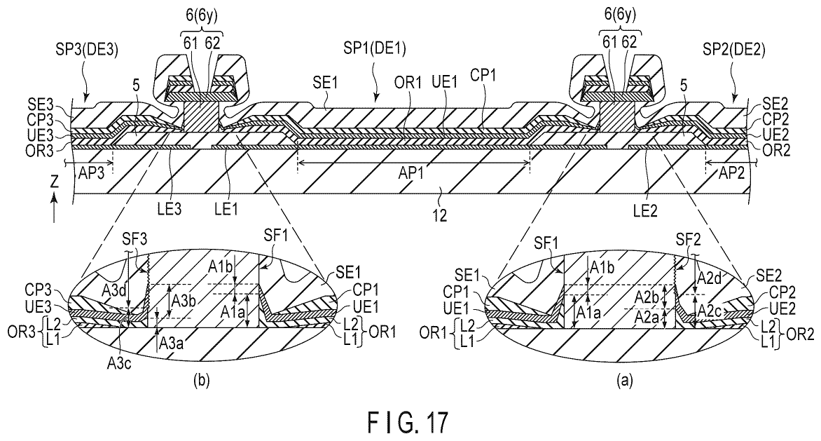

After processes P20 to P27 described above, as shown in FIG. 17, a substrate in which the first display element DE1 and the first sealing layer SE1 are formed in the first sub-pixel SP1, the second display element DE2 and the second sealing layer SE2 are formed in the second sub-pixel SP2, and the third display element DE3 and the third sealing layer SE3 are formed in the third sub-pixel SP3 can be obtained.

As expanded and shown in FIG. 17(b), the third organic layer OR3 is formed such that the height of the area A3a which is in contact with the third side surface SF3 is smaller than the height of the area Ala. The height of the area A3a is smaller than the height of the area A2a shown in FIG. 17(b). For example, the height of the area A3a can be adjusted depending on the deposition conditions during forming the third organic layer OR3, for example, an angle of extension of the deposition material released from a deposition source.

As described above, the height of the area A2a is equal to the height of the area A3c. Therefore, when the height of the area A3a is smaller than the height of the area A2a, the third upper electrode UE3 is also in contact with the area A3c.

The deposition conditions during forming the third upper electrode UE3 are the same as the deposition conditions during forming the first upper electrode UE1 and the second upper electrode UE2. Therefore, the third upper electrode UE3 is deposited on the third side surface SF3 at the same height as the first upper electrode UE1 deposited on the first side surface SF1, and the second upper electrode UE2 deposited on the second side surface SF2. As a result, the width of the area A3b where the third upper electrode UE3 is in contact with the third side surface SF3 is larger than the width of the area Alb where the first upper electrode UE1 is in contact with the first side surface SF1, and the width of the area A2b where the second upper electrode UE2 is in contact with the second side surface SF2.

After process P27, the resin layer 13, the sealing layer 14, and the resin layer 15 shown in FIG. 3 are formed in order (process P28). The display device DSP is thereby completed.

Advantages achieved by the display device DSP of the present embodiment and its manufacturing method will be described below.

In the display device DSP of the present embodiment, the first organic layer OR1 is in contact with the first side surface SF1. In manufacturing such a display device DSP, the first organic layer OR1 is also in contact with the second side surface SF2 of the lower portion 61 which is adjacent to the sub-pixel SP2, as shown in FIG. 10. Damages in the area A2c of the second side surface SF2, which is covered with the first organic layer OR1, can be thereby suppressed in the wet etching of the first upper electrode UE1 (process P9).

If the second side surface SF2 is not covered with the first organic layer OR1, the entire second side surface SF2 may be damaged by the wet etching. As a result, the entire second upper electrode UE2 to be formed later would be in contact with the damaged area and, if the damages were terrible, the second upper electrode UE2 might not be desirably conductive with the lower portion 61.

In contrast, in the present embodiment, the height of the area A2a where the second organic layer OR2 is in contact with the second side surface SF2 is smaller than the height of the area A1a where the first organic layer OR1 is in contact with the first side surface SF1. For this reason, the second upper electrode UE2 formed on the second organic layer OR2 is also in contact with the area A2c which is not damaged during the wet etching of the first upper electrode UE1. As a result, desirable conduction of the second upper electrode UE2 with the lower portion 61 can be secured.

Similarly, the second organic layer OR2 is in contact with the third side surface SF3 during the wet etching of the second upper electrode UE2 (process P17). As a result, damages in the area A3c of the third side surface SF3, which is covered with the second organic layer OR2, can be suppressed.

Furthermore, in the present embodiment, the height of the area A3a where the third organic layer OR3 is in contact with the third side surface SF3 is smaller than the height of the area A2a where the second organic layer OR2 is in contact with the second side surface SF2. For this reason, the third upper electrode UE3 formed on the third organic layer OR3 is also in contact with the area A3c which is not damaged during the wet etching of the second upper electrode UE2. As a result, desirable conduction of the third upper electrode UE3 with the lower portion 61 can be secured.

Thus, according to the present embodiment, the display device DSP which suppresses damages on the lower portion 61 caused by the wet etching of the upper electrodes UE1 and UE2 and which is excellent in reliability can be provided.

All of the display devices and manufacturing methods that can be implemented by a person of ordinary skill in the art through arbitrary design changes to the display devices and manufacturing methods described above as embodiments of the present invention come within the scope of the present invention as long as they are in keeping with the spirit of the present invention.

Various types of the modified examples are easily conceivable within the category of the ideas of the present invention by a person of ordinary skill in the art and the modified examples are also considered to fall within the scope of the present invention. For example, the above embodiments with addition, deletion, and/or designed change of their structural elements by a person having ordinary skill in the art, or the above embodiments with addition, omission, and/or condition change of their processes by a person having ordinary skill in the art are encompassed by the scope of the present inventions without departing the spirit of the inventions.

In addition, the other advantages of the aspects described in the embodiments, which are obvious from the descriptions of the present specification or which can be arbitrarily conceived by a person of ordinary skill in the art, are considered to be achievable by the present invention as a matter of course.

What is claimed is:

1. A display device comprising:
a first lower electrode;
a rib including a first pixel aperture overlapping with the first lower electrode;
a partition arranged on the rib;
a first upper electrode opposed to the first lower electrode; and
a first organic layer which is located between the first lower electrode and the first upper electrode, which is in contact with the first lower electrode through the first pixel aperture, and which emits light in accordance with a potential difference between the first lower electrode and the first upper electrode,
wherein
the partition includes a lower portion having a first side surface and an upper portion protruding from the first side surface, and
the first organic layer is in contact with the first side surface.

2. The display device of claim 1, wherein
the lower portion is conductive, and
the first upper electrode is in contact with the first side surface.

3. The display device of claim 1, further comprising:
a first sealing layer continuously covering the partition and a first display element which includes the first lower electrode, the first upper electrode, and the first organic layer.

4. The display device of claim 1, wherein
the first organic layer includes a first layer including a hole-injection layer and a second layer covering the first layer,
the first layer is not in contact with the first side surface, and
the second layer is in contact with the first side surface.

5. The display device of claim 1, further comprising:
a second lower electrode overlapping with a second pixel aperture of the rib;
a second upper electrode opposed to the second lower electrode; and
a second organic layer which is located between the second lower electrode and the second upper electrode, which is in contact with the second lower electrode through the second pixel aperture, and which emits light in accordance with a potential difference between the second lower electrode and the second upper electrode, wherein
the lower portion has a second side surface, and
the second organic layer is in contact with the second side surface.

6. The display device of claim 5, wherein
a height of an area where the first organic layer is in contact with the first side surface is different from a height of an area where the second organic layer is in contact with the second side surface.

7. The display device of claim 6, wherein
the height of the area where the first organic layer is in contact with the first side surface is larger than the height of the area where the second organic layer is in contact with the second side surface.

8. The display device of claim 5, wherein
a width in a height direction of the partition, of an area where the first upper electrode is in contact with the first side surface is smaller than a width in the height direction, of an area where the second upper electrode is in contact with the second side surface.

9. The display device of claim 5, wherein
an area of the first pixel aperture is larger than an area of the second pixel aperture.

10. The display device of claim 5, wherein
a thickness of the first organic layer is smaller than a thickness of the second organic layer.

11. A display device manufacturing method comprising:
forming a first lower electrode and a second lower electrode;
forming a rib including a first pixel aperture overlapping with the first lower electrode and a second pixel aperture overlapping with the second lower electrode;
forming on the rib a partition which includes a lower portion having a first side surface and a second side surface and which includes an upper portion protruding from the first side surface and the second side surface;
forming a first organic layer which is in contact with the first lower electrode and the second lower electrode through the first pixel aperture and the second pixel aperture, respectively, and which is in contact with the first side surface and the second side surface; and
forming a first upper electrode covering the first organic layer.

12. The method of claim 11, wherein
the lower portion is conductive, and
the first upper electrode is in contact with the first side surface and the second side surface.

13. The method of claim 11, further comprising:
forming a first sealing layer continuously covering the partition and a first display element which includes the first lower electrode, the first upper electrode, and the first organic layer.

14. The method of claim 12, comprising:
removing portions of the first upper electrode and the first organic layer, which are located above the second lower electrode and which are in contact with the second side surface, by etching;
forming a second organic layer which is in contact with the second lower electrode through the second pixel aperture; and
forming a second upper electrode covering the second organic layer.

15. The method of claim 14, wherein
the second upper electrode is in contact with an area of the second side surface, which is covered with the first organic layer during etching of the first upper electrode.

16. The method of claim 14, wherein
the second organic layer is in contact with the second side surface.

17. The method of claim 16, wherein
a height of an area where the first organic layer is in contact with the first side surface is different from a height of an area where the second organic layer is in contact with the second side surface.

18. The method of claim 17, wherein
the height of the area where the first organic layer is in contact with the first side surface is larger than the height of the area where the second organic layer is in contact with the second side surface.

19. The method of claim 11, wherein
an area of the first pixel aperture is larger than an area of the second pixel aperture.

20. The method of claim 14, wherein
a thickness of the first organic layer is smaller than a thickness of the second organic layer.
